(19) United States
(12) Patent Application Publication
(10) Pub. No.: US 2025/0129281 A1
(43) Pub. Date: Apr. 24, 2025

(54) CURABLE THERMALLY CONDUCTIVE COMPOSITION

(71) Applicant: DOW SILICONES CORPORATION, Midland, MI (US)

(72) Inventors: Yan ZHENG, Shanghai (CN); Dorab BHAGWAGAR, Auburn, MI (US)

(21) Appl. No.: 18/835,050

(22) PCT Filed: Feb. 7, 2022
(86) PCT No.: PCT/CN2022/075356

§ 371 Date: Aug. 1, 2024

(51) Int. Cl. C09K 5/14; C08G 77/12; C08G 77/20; C08K 9/06

(52) U.S. Cl. CPC C09K 5/14; C08G 77/12; C08G 77/20; C08K 9/06; C08K 2201/001; C08K 2201/005

(57) ABSTRACT

A curable thermally conductive composition contains: (A) an alkenyl-functional polyorganosiloxane having a viscosity in a range of 25 to 2000 millipascal*seconds; (B) a silyl-hydride functional polysiloxane crosslinker; (C) from 94 to 97 weight-percent of thermally conductive fillers that contain (c1) from 30 to less than 55 weight-percent of aluminum particles having a D50 of 60 micrometers or more; (c2) from 20 to 40 weight-percent of thermally conductive fillers having a D50 of 1 to 10 micrometers; (c3) from 8 to 20 weight-percent of thermally conductive fillers having a D50 of 0.1 to less than 1 micrometer; and (c4) optionally, from zero to 20 weight-percent of thermally conductive fillers other than (c1), having a D50 of 20 to 80 micrometers; and (D) from 0.1 to 2.5 weight-percent of a filler treating agent comprising a trialkoxysilyl diorganopolysiloxane, and optionally, an alkyl trialkoxysilane; where weight-percentages are relative to curable thermally conductive composition weight.

### FIELD

The present invention relates to curable thermally conductive compositions that contain thermally conductive fillers including aluminum particles having a D50 particle size in a range of 60 to 150 micrometers.

### INTRODUCTION

An industry drive to smaller and more powerful electronic devices has increased demands on thermally conductive compositions useful for dissipating heat generated in such devices. For instance, the telecommunications industry is going through a generational shift to 5G networks, which demand highly integrated electrical devices with smaller sizes and that brings a requirement for double the power requirements (1200 Watts from 600 Watts). The heat generated by the high power in the smaller devices would damage the device if not efficiently dissipated. Thermally conductive interface materials are often used in electronics to thermally couple heat generating components and heat dissipating components.

A challenge with thermally conductive interface materials is to provide a combination of both high thermal conductivity properties while being easily extrudable so as to allow precise application of the thermally conductive material on small components. In particular, it is desirably to provide a thermally conductive interface material that has an extrusion rate of at least 40 grams per minute as measured using the Extrusion Rate Test defined herein below and that cures to a material that has a thermal conductivity of at least 10 Watts per meter*Kelvin as measured using a hot disk according to ISO 22007-2. Thermal conductivity can be increased by increasing the amount of thermally conductive fillers, but that also reduces the extrusion rate for a composition which can even become a powdery paste. Therefore, meeting these two performance parameters is particularly challenging.

There remains a need to identify a thermally conductive composition that can simultaneously achieve the above described extrusion rate and thermal conductivity properties.

### SUMMARY

The present invention provides a thermally conductive interface material that has an extrusion rate of 40 grams per minute (g/min) or more as measured using the Extrusion Rate Test defined herein below and that cures to a material that has a thermal conductivity of at least 10 Watts per meter*Kelvin (W/m*K) using a hot disk according to ISO 22007-2. Surprisingly, it has been determined such a composition can be prepared from a curable polysiloxane composition (also as “curable thermally conductive composition”) that contains 94 to 97 weight-percent (wt %) of thermally conductive fillers that include 30 to less than 55 wt % of aluminum particles having a D50 particles size in a range of 60 to 150 micrometers (μm), where wt % is relative to curable polysiloxane composition weight.

In a first aspect, the present invention is a curable thermally conductive composition comprising:
(A) from 1.0 to 4.0 weight-percent of an alkenyl-functional polyorganosiloxane having a viscosity in a range of 25 to 2000 millipascal*seconds as determined by ASTM D445-21 using a glass capillary Cannon-Fenske type viscometer at 25 degrees Celsius, wherein the alkenyl-functional polyorganosiloxane has an average chemical structure (I):

R^{a}_{(3-c)}R′_{c}SiO—(R′R^{a}SiO)ₐ—(R^{a}₂SiO)_{b}—SiR′_{d}R^{a}_{(3-d)} (I)
where R^{a} is independently in each occurrence an alkyl group having 1 to 6 carbon atoms, R′ is independently in each occurrence an alkenyl group, subscript a≥0, subscript b>0, subscript c is zero or 1, subscript d is zero or 1, (a+b) is 20 to 350, and (a+c+d)≥2;
(B) a silyl-hydride functional polysiloxane crosslinker that contains at least two silyl-hydride groups per molecule and that is present at a concentration to provide a molar ratio of silicon-bonded hydrogen atoms to alkenyl groups for the composition of 0.4 to 1.5;
(C) from 94 to 97 weight-percent of thermally conductive fillers comprising:
(c1) from 30 to less than 55 weight-percent of aluminum particles having a D50 in a range of 60 to 150 micrometers;
(c2) from 20 to 40 weight-percent of thermally conductive fillers having a D50 in a range of 1 to 10 micrometers;
(c3) from 8 to 20 weight-percent of thermally conductive fillers having a D50 in a range of 0.1 to less than 1 micrometer; and
(c4) optionally, from zero to 20 weight-percent of thermally conductive fillers other than (c1), having a D50 in a range of 20 to 80 micrometers; and
(D) from 0.1 to 2.5 weight-percent of a filler treating agent comprising a trialkoxysilyl diorganopolysiloxane, and optionally, an alkyl trialkoxysilane;
where weight-percentages are relative to curable thermally conductive composition weight.

In a second aspect, the present invention is a process for using the curable thermally conductive composition of the first aspect. The process comprises: applying the curable thermally conductive composition between and in contact with two components and then curing the curable composition while in place between the components.

In a third aspect, the present invention is an article comprising the curable thermally conductive composition of the first aspect between and in contact with two components of the article, wherein the curable thermally conductive composition is in either a cured or non-cured form.

### DETAILED DESCRIPTION

Test methods refer to the most recent test method as of the priority date of this document when a date is not indicated with the test method number. References to test methods contain both a reference to the testing society and the test method number. The following test method abbreviations and identifiers apply herein: ASTM refers to ASTM International methods and ISO refers to International Organization for Standards.

Products identified by their tradename refer to the compositions available under those tradenames on the priority date of this document.

“And/or” means “and, or as an alternative”. All ranges include endpoints unless otherwise indicated.

“Spherical” shaped particles refer to particles that have an aspect ratio of 1.0+/−0.2. Determine the aspect ratio of a particle using scanning electron microscope (SEM) imaging and by taking the average ratio of the longest dimension (major axis) and shortest dimension (minor axis) of at least ten particles.

“Irregular” shaped particles have an aspect ratio other than 1.0+/−0.2 and have at least three faces evident by SEM imaging (distinguishing the particles from “platelets”, which have 2 faces).

Particle size of thermally conductive fillers (which is used interchangeable with “average particle size” and “D50”) refers to the volume-weighted median value of particle diameter distribution (D50) using a Mastersizer™ (trademark of Malvern Instruments Limited) 3000 laser diffraction particle size analyzer from Malvern Instruments.

Determine viscosity, unless otherwise stated, according to ASTM D445-21 using a glass capillary Cannon-Fenske type viscometer at 25 degrees Celsius (° C.).

The curable thermally conductive composition of the present invention can undergo a crosslinking reaction (“curing”). In the present composition, the crosslinking reaction is a hydrosilylation reaction between alkenyl-functional polyorganosiloxane components and silyl-hydride (SiH) functional polysiloxane crosslinker.

The alkenyl-functional polyorganosiloxane useful in the present invention have two or more alkenyl groups per molecule. “Alkenyl” means a branched or unbranched, monovalent hydrocarbon group having one or more carbon-carbon double bonds. The alkenyl groups can be terminal, pendant, or a combination of both terminal and pendant. “Terminal” groups are on end siloxane groups of a molecule. “End” siloxane groups are attached to only one other siloxane group. “Pendant” groups are on interior siloxane group—siloxane groups bound to at least two other siloxane groups—of the molecule. “Siloxane group” is a group containing SiO that is bound to another Si through the oxygen of the SiO. Desirably, the alkenyl-functional polydiorganosiloxane has an average of one or more terminally alkenyl groups per molecule. The alkenyl-functional polyorganosiloxane has a viscosity in a range of 25 to 2000 millipascal*seconds (mPa*s). Th alkenyl-functional polyorganosiloxane may be a combination of two or more alkenyl-functional polyorganosiloxanes that may differ in one or more properties selected from molecular weight, structure, siloxane units and sequence. When the alkenyl-functional polyorganosiloxane is a combination of more than one alkenyl-functional polyorganosiloxane then the viscosity is the combined viscosity of alkenyl-functional polyorganosiloxanes. The viscosity of the alkenyl-functional polyorganosiloxane is 25 mPa*s or more, and can be 30 mPa*s or more, 40 mPa*s or more, 50 mPa*s or more, 60 mPa*s or more, 70 mPa*s or more, 75 mPa*s or more, 78 mPa*s or more, 80 mPa*s or more, 100 mPa*s or more, 125 mPa*s or more, 150 mPa*s or more, 175 mPa*s or more, even 200 mPa*s or more, while at the same time is 2000 mPa*s or less, and can be 1500 mPa*s or less, 1000 mPa*s or less, 500 mPa*s or less, 400 mPa*s or less, 300 mPa*s or less, 200 mPa*s or less, 150 mPa*s or less, 100 mPa*s or less, 90 mPa*s or less, even 80 mPa*s or less, as determined by using a glass capillary Cannon-Fenske type viscometer at 25 degrees Celsius (° C.) according to ASTM D445-21.

The alkenyl-functional polyorganosiloxane useful in the present invention may have an average chemical structure (I):

R^{a}_{(3-c)}R′_{c}SiO—(R′R^{a}SiO)ₐ—(R^{a}₂SiO)_{b}—SiR′_{d}R^{a}_{(3-d)} (I)
where R^{a} is independently in each occurrence an alkyl group having 1 to 6 carbon atoms, R′ is independently in each occurrence an alkenyl group, subscript a≥0, subscript b>0, subscript c is zero or 1, subscript d is zero or 1, (a+c+d)≥2, and (a+b) is 20 to 350. The R^{a} group can have one carbon or more, 2 carbons or more, 3 carbons or more, 4 carbons or more, even 5 carbons or more while at the same time 6 carbons or fewer, 5 carbons or fewer, 4 carbons or fewer, 3 carbons or fewer, or even 2 carbons or fewer. For example, R^{a} can be CH₃, CH₂CH₃, (CH₂)₂CH₃, (CH₂)₃CH₃, (CH₂)₄CH₃, and (CH₂)₅CH₃. Desirably, each R^{a} is methyl. The alkenyl group represented by R′ typically have from 2 to 8 carbon atoms, from 2 to 6 carbon atoms or from 2 to 4 carbon atoms. Suitable alkenyl groups for R′ are exemplified by an alkenyl group such as vinyl, allyl, butenyl, and hexenyl. Desirably, R′ is vinyl. More desirably, subscript a is zero, subscript c is 1, subscript d is 1, and each R^{a} is methyl.

Subscript a is the average number of (R′R^{a}SiO) groups per molecule. Subscript b is the average number of (R^{a}₂SiO) groups per molecule. Desirably, a quantity (a+b) is 25 or more, and can be 30 or more, 40 or more, 50 or more, 60 or more, 70 or more, 80 or more, 90 or more, 100 or more, 120 or more, 140 or more, 160 or more, 180 or more, 200 or more, 220 or more, 240 or more, 260 or more, 280 or more, 300 or more, 320 or more, even 340 or more, while at the same time is typically 350 or less, and can be 340 or less, 320 or less, 300 or less, 280 or less, 260 or less, 240 or less, 240 or less, 220 or less, 200 or less, 180 or less, 160 or less, 140 or less, 120 or less, 100 or less, 80 or less, 60 or less, even 40 or less.

Desirably, a quantity (a+c+d) is 2 or more, even 3 or more, while at the same time is typically 30 or less, and can be 20 or less, 10 or less, or even 3 or less.

Examples of suitable alkenyl-functional polyorganosiloxanes include i) vinyldimethylsiloxy-terminated polydimethylsiloxane, ii) dimethylvinylsiloxy-terminated poly(dimethylsiloxane/methylvinylsiloxane), iii) dimethylvinylsiloxy-terminated polymethylvinylsiloxane, iv) trimethylsiloxy-terminated poly(dimethylsiloxane/methylvinylsiloxane), v) trimethylsiloxy-terminated polymethylvinylsiloxane, vi) dimethylvinylsiloxy-terminated poly(dimethylsiloxane/methylvinylsiloxane), or mixtures thereof.

More desirably, the alkenyl-functional polyorganosiloxane comprises, or consists of, one or any combination of more than one vinyldimethylsiloxy-terminated polydimethylpolysiloxane having the average chemical structure (II):

Vi(CH₃)₂SiO—((CH₃)₂SiO)_{b}—Si(CH₃)₂Vi (II)
where Vi represents vinyl, and subscript b is the average number of ((CH₃)₂SiO) groups per molecule and has a value of 20 or more, and can be 25 or more, 30 or more, 40 or more, 50 or more, 60 or more, 70 or more, 80 or more, 90 or more, 100 or more, 120 or more, 140 or more, 160 or more, 180 or more, 200 or more, 220 or more, 240 or more, 260 or more, 280 or more, 300 or more, 320 or more, even 340 or more, while at the same time typically have a value of 350 or less, and can be 340 or less, 320 or less, 300 or less, 280 or less, 260 or less, 240 or less, 240 or less, 220 or less, 200 or less, 180 or less, 160 or less, 140 or less, 120 or less, 100 or less, 80 or less, 60 or less, even 40 or less. For example, the alkenyl-functional polyorganosiloxane can be a vinyldimethylsiloxy terminated polydimethylsiloxane having a viscosity of 78 mPa*s and containing 1.25 weight-percent (wt %) vinyl groups relative to molecular weight such as that available from Gelest under the name SMS-V21.

The concentration of the alkenyl-functional polyorganosiloxane is 1.0 wt % or more, and can be 1.5 wt % or more, 2.0 wt % or more, 2.4 wt % or more, 2.5 wt % or more, 2.6 wt % or more, 2.7 wt % or more, 2.8 wt % or more, 2.9 wt % or more, even 3.0 wt % or more, while at the same time is generally 4 wt % or less, and can be 3.8 wt % or less, 3.5 wt % or less, 3.3 wt % or less, 3.0 wt % or less, 2.9 wt % or less, 2.8 wt % or less, 2.7 wt % or less, or even 2.6 wt % or less, based on the weight of the curable thermally conductive composition.

The curable thermally conductive composition of the present invention further comprises at least one silyl-hydride (SiH) functional polysiloxane crosslinker (also as “crosslinker”). The SiH functional polysiloxane crosslinker contains at least two silyl-hydride groups (i.e., containing at least two silicon-bonded hydrogen atoms), or even 3 or more, per molecule. The SiH groups can be pendant, terminal or a combination of both pendant and terminal. The SiH functional polysiloxane crosslinker can have an average chemical structure (III):

R^{b}₍₃₋ₕ₎HₕSiO—(HR^{b}SiO)ₑ—(R^{b}₂SiO)_{f}—SiH_{h′}R^{b}_{(3-h′)} (III)
where R^{b} is independently in each occurrence selected from an alkyl group having from 1 to 6 carbon atoms and phenyl. The R^{b} group can have one carbon or more, 2 carbons or more, 3 carbons or more, 4 carbons or more, even 5 carbons or more while at the same time 6 carbons or fewer, 5 carbons or fewer, 4 carbons or fewer, 3 carbons or fewer, or even 2 carbons or fewer. Desirably, the R^{b} group is independently in each occurrence selected from methyl and phenyl groups.

H is a hydrogen atom;
Subscripts h and h′ refer the average number of terminal hydrogen atoms on either end and each are independently in each occurrence selected from a value in a range of zero to 3 provided the combination of a, h and h′ is at least 2. Desirably, h and h′ are independently in each occurrence zero or more, one or more, even 2 or more while at the same time 3 or less, 2 or less, even one or less. More desirably, h and h′ have the same value. Most desirably, h and h′ are both zero;
Subscript e is the average number of (HR^{b}SiO) groups per molecule. If h and h′ are both zero then e is in a range of 2 to 30. If h and h′ are both non-zero then subscript e can be zero to 30 provided the combination of a, h and h′ is 2 or more. Desirably, subscript e is 1 or more, and can be two or more and can be 3 or more, 4 or more, 5 or more, 6 or more, 7 or more, 8 or more, even 9 or more and at the same time typically is 30 or less, and can be 25 or less, 20 or less, 15 or less, 10 or less, 9 or less, 8 or less, 7 or less, 6 or less, 5 or less, 4 or less, 3 or less, even 2 or less;
Subscript f is the average number of (R^{b}₂SiO) groups per molecule. Generally, subscript f is 5 or more, 10 or more, 20 or more, 25 or more, 30 or more, 40 or more, 50 or more, and can be 75 or more, 100 or more, 125 or more, 150 or more, 175 or more, even 190 or more while at the same time is typically 200 or less, 175 or less, 150 or less, 125 or less, 100 or less, 75 or less, 50 or less, 40 or less, 30 or less, 25 or less, or even 20 or less.

Suitable SiH functional polysiloxane crosslinkers may include, for example, trimethylsiloxy-terminated poly (dimethylsiloxane/methylhydrogensiloxane), trimethylsiloxy-terminated polymethylhydrogensiloxane, hydrogen-terminated polydimethylsiloxane, hydrogen-terminated poly (dimethylsiloxane/methylhydrogensiloxane), or mixtures thereof. The crosslinker may be a combination of two or more crosslinkers that may differ in one or more properties selected from molecular weight, structure, siloxane units and sequence. Suitable commercially available SiH crosslinkers include those available under the names HMS-071, HMS-501 and DMS-H11 all available from Gelest. Desirably, the crosslinker can be one or a combination of both polymers selected from a group consisting of: (i) trimethyl terminated dimethyl-co-hydrogen methyl polysiloxane with a viscosity of 10-15 millipascals*seconds and containing 0.36 weight-percent hydrogen in silylhydride groups; and (ii) hydride terminated polydimethylsiloxane having a viscosity in a range of 7-10 millipascals*seconds and containing 0.16 weight-percent hydrogen in silylhydride groups.

The concentration of the SiH functional polysiloxane crosslinker is sufficient to provide a molar ratio of silicon-bonded hydrogen atoms from the crosslinker to alkenyl groups (desirably, vinyl groups) in the curable thermally conductive composition (also as “SiH/Vi ratio”) that is 0.4 or higher, and can be 0.5 or higher, 0.6 or higher, 0.7 or higher, 0.8 or higher, even 0.9 or higher, while at the same time is 1.5 or less, and can be 1.4 or less, 1.2 or less, 1.0 or less, 0.9 or less, 0.8 or less, 0.7 or less, or even 0.6 or less. The SiH/Vi ratio determines the extent of crosslinking that occurs when the curable thermally conductive composition cures. If the SiH/Vi ratio is too low, then the composition tends not to be sufficiently cured. If the SiH/Vi ratio is too high then the composition cures so much it may become brittle and suffer from surface cracking.

The curable thermally conductive composition of the present invention further comprises thermally conductive fillers (C). The total concentration of thermally conductive fillers is 94 wt % or more, and can be 94.4% or more, 94.5 wt % or more, 95 wt % or more, 95.4% or more, even 95.5 wt % or more, while at the same time is typically 97 wt % or less, and can be 96.5 wt % or less, 96 wt % or less, 95.5 wt % or less, 95 wt % or less, even 94.5 wt % or less, based on the weight of the curable thermally conductive composition.

The thermally conductive filler (C) useful in the present invention comprises, and can consist of, a combination of at least three, optionally four, different thermally conductive fillers, i.e., (c1), (c2), (c3), and optionally (c4), described below.

The first thermally conductive filler (c1) is aluminum particles having a D50 particle size of 60 μm or more, and can have a D50 of 65 μm or more, 70 μm or more, 75 μm or more, 80 μm or more, 85 μm or more, or even 90 μm or more, while at the same time have a D50 particle size of 150 μm or less, and can have a D50 of 140 μm or less, 130 μm or less, 120 μm or less, 110 μm or less, 100 μm or less, 95 μm or less, 90 μm or less, 85 μm or less, 80 μm or less, 75 μm or less, or even 70 μm or less. Desirably, the aluminum particles have a D50 of 70 to 95 μm, and more desirably, 70 to 90 μm. The aluminum particles may have any of shapes, including granular, globular and acicular shapes, and desirably, the aluminum particles are spherical shape. The concentration of the aluminum particles (c1) is 30 wt % or more, and can be 31 wt % or more, 34 wt % or more, 35 wt % or more, 36 wt % or more, 38 wt % or more, 40 wt % or more, 42 wt % or more, 44 wt % or more, or even 46 wt % or more while at the same time is less than 55 wt %, and can be 54 wt % or less, 53 wt % or less, 52 wt % or less, 51 wt % or less, 50 wt % or less, 48 wt % or less, 47 wt % or less, 46 wt % or less, 45 wt % or less, 42 wt % or less, 40 wt % or less, 38 wt % or less, or even 35 wt % or less, based on the weight of the curable thermally conductive composition. Desirably, the first thermally conductive filler is 30 to 52 wt % of aluminum particles having a D50 of 70 to 90 μm, based on the weight of the curable thermally conductive composition.

The second thermally conductive filler (c2) has a D50 particle size of 1 μm or more, and can have a D50 of 1.5 μm or more, 2 μm or more, 3 μm or more, 4 μm or more, or even 5 μm or more, while at the same time have a D50 particle size of 10 μm or less, and can have a D50 of 9 μm or less, 8 μm or less, 7 μm or less, 6 μm or less, or even 5 μm or less. The concentration of the second thermally conductive filler is 20 wt % or more, and can be 22 wt % or more, 25 wt % or more, 26 wt % or more, 27 wt % or more, 28 wt % or more, 29 wt % or more, even 30 wt % or more while at the same time is 40 wt % or less, and can be 38 wt % or less, 36 wt % or less, 35 wt % or less, 34 wt % or less, 33.5 wt % or less, 33 wt % or less, 32 wt % or less, or even 31 wt % or less, based on the weight of the curable thermally conductive composition. Desirably, the second thermally conductive filler is one or a combination of both of aluminum nitride and aluminum oxide. More desirably, the second thermally conductive filler is one or both of spherical aluminum oxide and irregular aluminum nitride. Desirably, the second thermally conductive filler is selected from 30 to 35 wt % spherical aluminum oxide particles having a D50 of 2 to 5 μm; or from 5 to 25 wt % of spherical aluminum oxide particles having a D50 of 2 to 5 μm in combination with from 5 to 20 wt % of irregular aluminum nitride particles having a D50 of 1 to 5 μm.

The third thermally conductive filler (c3) has a D50 particle size of 0.1 μm or more and can have a D50 of 0.2 or more, 0.3 μm or more, 0.5 μm or more, 0.7 μm or more, 0.8 μm or more, even 0.9 μm or more, while at the same time has a D50 particle size less than 1 μm, and can have a D50 of 0.8 μm or less, 0.6 μm or less, 0.4 μm or less, or even 0.2 μm or less. The concentration of the third thermally conductive filler (c3) is 8 wt % or more, and can be 10 wt % or more, 12 wt % or more, 14 wt % or more, 16 wt % or more, even 18 wt % or more while at the same time is 20 wt % or less, and can be 19 wt % or less, 18 wt % or less, 17 wt % or less, 15 wt % or less, 13 wt % or less, or even 11 wt % or less, based on the weight of the curable thermally conductive composition. The third thermally conductive filler may be selected from zinc oxide, aluminum oxide, or mixtures thereof. Desirably, the third thermally conductive filler is one or both of crushed or irregular zinc oxide and spherical aluminum oxide. More desirably, the third thermally conductive filler is selected from 12 to 18 wt % of irregular zinc oxide particles having a D50 of 0.1 to 0.5 μm, or 8 to 13 wt % of spherical aluminum oxide particles having a D50 of 0.2 to 0.8 μm.

The fourth thermally conductive filler (c4), that is other than the aluminum particles (c1) described above, has a D50 particle size of 20 μm or more, and can have a D50 of 25 μm or more, 30 μm or more, 35 μm or more, 40 μm or more, 45 μm or more, even 50 μm or more, while at the same time has a D50 particle size of 80 μm or less, and can have a D50 of 70 μm or less, 60 μm or less, 55 μm or less, 50 μm or less, or even 45 μm or less. The concentration of the fourth thermally conductive filler is zero or more, and can be 2 wt % or more, 4 wt % or more, 6 wt % or more, 8 wt % or more, 10 wt % or more, 12 wt % or more, 14 wt % or more, 16 wt % or more, even 18 wt % or more while at the same time is 20 wt % or less, and can be 19 wt % or less, 17 wt % or less, 15 wt % or less, 13 wt % or less, or even 11 wt % or less, based on the weight of the curable thermally conductive composition. The fourth thermally conductive filler may be selected from one or any combination of more than one of aluminum nitride, aluminum oxide, magnesium oxide, and boron nitride. Desirably, the fourth thermally conductive filler is aluminum nitride particles. More desirably, the fourth thermally conductive filler, when present, is from 10 to 20 wt % of spherical aluminum nitride particles having a D50 in a range of 20 to 50 μm.

The thermally conductive filler useful in the present invention can comprise fillers in addition to these four thermally conductive fillers described above or be free of thermally conductive fillers other than these four (i.e., the thermally conductive filler consists of (c1), (c2), (c3) and optionally (c4)).

The particles described above each independently can have any shape such as spherical, irregular, crushed or platelet. Desirably, each thermally conductive filler other than (c1) described above is independently selected from a group consisting of aluminum particles, aluminum nitride particles, aluminum oxide particles, zinc oxide particles, and boron nitride particles.

Desirably, the thermally conductive filler useful in the present invention comprises or consists of: (c1) from 30 to 52 wt % of aluminum particles having a D50 of 70 to 90 μm; (c2) from 30 to 35 wt % of aluminum oxide particles having a D50 of 2 to 5 μm, or a combination of 5 to 25 wt % of aluminum oxide particles having a D50 of 2 to 5 μm and 5 to 20 wt % of aluminum nitride particles having a D50 of 1 to 5 μm; (c3) from 12 to 18 wt % of zinc oxide particles having a D50 of 0.1 to 0.5 μm, or from 8 to 13 wt % of aluminum oxide particles having a D50 of 0.2 to 0.8 μm; and optionally (c4) from zero to 20 wt % of aluminum nitride particles having a D50 of 20 to 50 μm.

The curable thermally conductive composition of the present invention comprises one or a combination of more than one filler treating agent (D). The filler treating agent (D) comprises, or consists of, one or any combination of more than one trialkoxysilyl diorganopolysiloxane, which is a diorganopolysiloxane that contains a —Si(OR)₃ group, where R^{e} is independently in each occurrence as described for R^{e} herein below in (IV). Desirably, the trialkoxysilyl diorganopolysiloxane is a mono-trialkoxysiloxy terminated diorganopolysiloxane. Suitable monotrialkoxysiloxy-terminated diorganopolysiloxanes include those having the average chemical structure (IV):

R^{c}₃SiO[R^{d}₂SiO]_{g}Si(OR^{e})₃ (IV)
where R^{c}, R^{d}, and R^{e} are each independently in each occurrence selected from hydrocarbyls having from 1 to 10 carbon atoms such as alkyl and aryl groups, for example, having 1 or more, 2 or more, 3 or more, 4 or more, 5 or more, 6 or more, 7 or more, even 8 or more carbon atoms while at the same time typically having 10 or fewer, 8 or fewer, 6 or fewer, 4 or fewer, even 2 or fewer carbon atoms; and subscript g typically has a value of 20 or more, 25 or more, 30 or more, 40 or more, 50 or more, 60 or more, 70 or more, 80 or more, 90 or more, 100 or more, or even 110 or more, while at the same time typically has a value of 200 or less, and can be 150 or less, 125 or less, 120 or less, 110 or less, 100 or less, 90 or less, 80 or less, 70 or less, 60 or less, 50 or less, 40 or less, or even 30 or less. Desirably, subscript g has a value in a range of 25 to 110. Each R^{c}, R^{d}, and R^{e} can be the same or different. Suitable alkyl groups for R^{c}, R^{d}, and R^{e} are exemplified by methyl, ethyl, propyl (e.g., iso-propyl and/or n-propyl), butyl (e.g., isobutyl, n-butyl, tert-butyl, and/or sec-butyl), pentyl (e.g., isopentyl, neopentyl, and/or tert-pentyl), hexyl, as well as branched saturated hydrocarbon groups of 6 carbon atoms. R^{c}, R^{d}, and R^{e} each can be independently an alkyl group such as methyl, ethyl, and propyl. Desirably, each R^{c}, R^{d}, and R^{e} is methyl. Suitable aryl groups for R^{c}, R^{d}, and R^{e} may include phenyl and dimethyl phenyl. A particularly desirable monotrialkoxysiloxy-terminated diorganopolysiloxane has the average chemical formula (CH₃)₃SiO[(CH₃)₂SiO]₃₀Si(OCH₃)₃. Suitable mono-trialkoxysiloxy terminated dimethylpolysiloxanes can be synthesized according the teachings in US2006/0100336.

The filler treating agent (D) useful in the present invention may comprise or be free of one or a combination of more than one alkyl trialkoxysilane. Suitable alkyl trialkoxysilanes include those having the chemical formula (V):

R^{f}Si(OR^{g})₃ (V)
where R^{f} is independently in each occurrence an alkyl group having 1 or more, 2 or more, 3 or more, 4 or more, 5 or more, 6 or more, 7 or more, 8 or more, 9 or more, or even 10 or more carbon atoms, while at the same time typically an alkyl having 20 or less, 18 or less, 16 or less, 14 or less, 12 or less, or even 10 or less carbon atoms; and R^{g} is independently in each occurrence an alkyl having 1 or more, 2 or more, 3 or more, 4 or more, or even 5 or more carbon atoms, while at the same time generally having 6 or less, 5 or less, 4 or less, 3 or less, or even 2 or less carbon atoms. Desirably, R^{f} is independently in each occurrence an alkyl group having from 6 to 20 carbon atoms. R^{g} is desirably methyl so as to form methoxyl groups attached to the silicon atom. A particularly desirably alkyl trialkoxysilane is n-decyltrimethoxysilane. Suitable alkyl trialkoxysilanes include n-decyltrimethoxysilane available from The Dow Chemical Company as DOWSIL™ Z-6210 Silane (DOWSIL is a trademark of The Dow Chemical Company) or under the name SID2670.0 from Gelest.

The filler treating agent useful in the present invention may be present at a total concentration of 0.1 wt % or more, and can be 0.2 wt % or more, 0.3 wt % or more, 0.4 wt % or more, 0.5 wt % or more, 0.6 wt % or more, 0.7 wt % or more, 0.8 wt % or more, 0.9 wt % or more, 1.0 wt % or more, 1.2 or more, 1.3 wt % or more, even 1.4 wt % or more, while at the same time is typically 2.5 wt % or less, and can be 2.2 wt % or less, 2.0 wt % or less, 1.8 wt % or less, 1.6 wt % or less, 1.4 wt % or less, 1.3 wt % or less, or even 1.2 wt % or less, based on the weight of the curable thermally conductive composition. Desirably, the trialkoxysilyl diorganopolysiloxane is present at a concentration of 0.3 wt % or more, and can be 0.4 wt % or more, 0.5 wt % or more, 0.6 wt % or more, 0.7 wt % or more, 0.8 wt % or more, 0.9 wt % or more, 1.0 wt % or more, 1.1 wt % or more, 1.2 wt % or more, 1.3 wt % or more, or even 1.4 wt % or more, while at the same time is typically present at a concentration of 2.5 wt % or less, and can be 2.2 wt % or less, 2.0 wt % or less, 1.9 wt % or less, 1.8 wt % or less, 1.7 wt % or less, 1.6 wt % or less, 1.5 wt % or less, or even 1.4 wt % or less, based on the weight of the curable thermally conductive composition. At the same time, or alternatively, the alkyltrialkoxysilane may be present at a concentration of zero or more, and can be 0.01 wt % or more, 0.05 wt % or more, 0.1 wt % or more, 0.2 wt % or more, 0.3 wt % or more, or even 0.4 wt % or more while at the same time is typically present at a concentration of 0.5 wt % or less, and can be 0.4 wt % or less, 0.3 wt % or less, or even 0.2 wt % or less, based on the weight of the curable thermally conductive composition. For example, the curable thermally conductive composition can comprise (CH₃)₃SiO[(CH₃)₂SiO]₃₀Si(OCH₃)₃ or its combination with n-decyltrimethoxysilane. Desirably, the curable thermally conductive composition comprises, based on the weight of the curable thermally conductive composition, from zero to 0.3 wt % of n-decyltrimethoxy silane and from 1.0 to 1.5 wt % of monotrimethoxysiloxy and trimethylsiloxy terminated polydimethylsiloxane having the average chemical structure (CH₃)₃SiO[(CH₃)₂SiO]₃₀Si(OCH₃)₃.

The curable thermally conductive composition may comprise or be free of one or a combination of more than one platinum-based hydrosilylation reaction catalyst (E). Such hydrosilylation reaction catalyst may include compounds and complexes such as platinum (0)-1,3-divinyl-1,1,3,3-tetramethyldisiloxane (Karstedt's catalyst), H₂PtCl₆, di-μ.-carbonyl di-.π.-cyclopentadienyldinickel, platinum-carbonyl complexes, platinum-divinyltetramethyldisiloxane complexes, platinum cyclovinylmethylsiloxane complexes, platinum acetylacetonate (acac), platinum black, platinum compounds such as chloroplatinic acid, chloroplatinic acid hexahydrate, a reaction product of chloroplatinic acid and a monohydric alcohol, platinum bis(ethylacetoacetate), platinum bis(acetylacetonate), platinum dichloride, and complexes of the platinum compounds with olefins or low molecular weight organopolysiloxanes or platinum compounds microencapsulated in a matrix or core-shell type structure. The hydrosilylation reaction catalyst can be part of a solution that includes complexes of platinum with low molecular weight organopolysiloxanes that include 1,3-diethenyl-1,1,3,3-tetramethyldisiloxane complexes with platinum. These complexes may be microencapsulated in a resin matrix (typically, in a phenyl resin) or non-encapsulated. Exemplary hydrosilylation reaction catalysts are described in U.S. Pat. No. 3,159,601 and 3,220,972. The catalyst can be 1,3-diethenyl-1,1,3,3-tetramethyldisiloxane complex with platinum.

Typically, the platinum-based hydrosilylation reaction catalyst (E) is present at a concentration sufficient to provide a platinum concentration of 0.01 wt % or more, 0.03 wt % or more, 0.04 wt % or more, 0.05 wt % or more, even 0.06 wt % or more while at the same time typically provide a platinum concentration of 0.6 wt % or less, and can be 0.5 wt % or less, 0.4 wt % or less, 0.3 wt % or less, 0.2 wt % or less, 0.1 wt % or less, 0.09 wt % or less, 0.08 wt % or less, 0.07 wt % or less, 0.06 wt % or less, 0.05 wt % or less, or even 0.04 wt % or less, based on the weight of the curable thermally conductive composition.

The curable thermally conductive composition of the present invention can further comprise or be free of one or a combination of more than one hydrosilylation reaction inhibitor (F) (also as “inhibitor”). Inhibitors can serve to stabilize the curable thermally conductive composition from premature curing and provide storage stability to the composition. Examples of suitable inhibitors include any one or any combination of more than one of acetylene-type compounds such as 2-methyl-3-butyn-2-ol; 3-methyl-1-butyn-3-ol; 3,5-dimethyl-1-hexyn-3-ol; 2-phenyl-3-butyn-2-ol;3-phenyl-1-butyn-3-ol; 1-ethynyl-1-cyclohexanol; 1,1-dimethyl-2-propynyl)oxy)trimethylsilane; and methyl(tris(1,1-dimethyl-2-propynyloxy))silane; ene-yne compounds such as 3-methyl-3-penten-1-yne and 3,5-dimethyl-3-hexen-1-yne; triazols such as benzotriazole; hydrazine-based compounds; phosphines-based compounds; mercaptan-based compounds; cycloalkenylsiloxanes including methylvinylcyclosiloxanes such as 1,3,5,7-tetramethyl-1,3,5,7-tetravinyl cyclotetrasiloxane and 1,3,5,7-tetramethyl-1,3,5,7-tetrahexenyl cyclotetrasiloxane.

The concentration of the inhibitor is zero or more, and can be 0.001 wt % or more, 0.002 wt % or more, even 0.003 wt % or more while at the same time is typically 0.5 wt % or less, and can be 0.3 wt % or less, 0.1 wt % or less, 0.05 wt % or less, 0.01 wt % or less, 0.005 wt % or less, 0.004 wt % or less, even 0.003 wt % or less, based on the weight of the curable thermally conductive composition.

The curable thermally conductive composition of the present invention achieves an extrusion rate (ER) of 40 g/min or more. Determine extrusion rates herein at a pressure of 0.62 MegaPascals (MPa) and 25° C. with a standard 30 cubic centimeters EFD syringe package (further details provided below under Extrusion Rate Test). The thermally conducive composition can have an extrusion rate of 45 g/min or more, 50 g/min or more, 60 g/min or more, or even 70 g/min or more. ER is a useful characteristic as a measure of extrudability, viscosity, dispensability and usability, which, for example, makes the curable thermally conductive composition easily dispensable for applying onto another material such as electronic components or heat sinks. At the same time, the curable thermally conductive composition of the present invention provides a thermal conductivity of at least 10.0 W/m*K or even 11.0 W/m*K or more, as measured using a hot disk according to ISO 22007-2 with cured samples (further details provided below under Thermal Conductivity Test). Having such a high thermal conductivity and by being easily dispensable makes the curable thermally conductive composition particularly useful as a thermally conductive interface material to efficiently transfer heat between two components. Thermally conductive interface materials are typically used to thermally couple heat generating components and heat dissipating components, especially in electronics. The curable thermally conductive composition may also have good uniformity and stability, as indicated by no coarse or powdery surface, and no oil separation, as determined by visual inspection.

The curable thermally conductive composition of the present invention may comprise or be free of one or a combination of more than one solvent. The concentration of solvent can be less than 0.01 wt %, less than 0.005 wt %, or even zero, based on the weight of the curable thermally conductive composition. Desirably, the curable thermally conductive composition is substantially free of a solvent, i.e., contains no solvent or may contain trace amounts of residual solvents from delivery of starting materials in the composition. The concentration of the solvent can be measured by gas chromatography (GC). If the amount of solvents is too high, voids tend to be generated during curing the curable thermally conductive composition, which gives poor surface appearance or even results in a decreased thermal conductivity. The solvent can be an organic solvent such as an aliphatic or aromatic hydrocarbon, which is saturated or unsaturated, such as benzene, toluene, xylene, hexane, heptane, octane, iso-paraffin, hydrocarbon compounds of 8 to 18 carbon atoms and at least one aliphatic unsaturation per molecule such as tetradecene; a ketone such as acetone, methyl ethyl ketone, or methyl isobutyl ketone; an ester acetate such as ethyl acetate or isobutyl acetate; an ether such as a glycol ether such as propylene glycol methyl ether, dipropylene glycol methyl ether, and propylene glycol n-butyl ether, diisopropyl ether or 1,4-dioxane; a cyclic or linear siloxane having an average degree of polymerization from 3 to 10 such as hexamethylcyclotrisiloxane, octamethylcyclotetrasiloxane, and/or decamethylcyclopentasiloxane; or mixtures thereof. The curable thermally conductive composition does not require the use of any solvents such as those described above to achieve the desired ER (i.e., good processability) and TC properties above. The present invention also relates to a method of preparing the curable thermally conductive composition, the method comprising: admixing the alkenyl-functional polyorganosiloxane, the SiH polysiloxane crosslinker, the thermally conductive fillers, the filler treating agent, and optionally, the hydroxylation reaction catalyst and the inhibitor.

The present invention also includes a process for using the curable thermally conductive composition, the process comprising applying the curable thermally conductive composition between and in contact with two components and then curing the curable composition while in place between the components. Applying of the curable thermally conductive composition can involve extruding the curable thermally conductive composition. Curing can be conducted at 20 to 40° C. or by heating at elevated temperatures greater than 40° C., such as from 60 to 150° C. or from 80 to 120° C. Due to the low concentration or absence of the solvent in the curable thermally conductive composition, the process does not involve (that is, is free of) an extra procedure for removal of the solvent, e.g., stripping off or evaporating the solvent. While still affording the resulting composition with desired ER and TC properties as described above, the curable thermally conductive composition enables the process for using the composition without the aid of a solvent and also makes it applicable to dispense (e.g., by extrusion) the composition directly onto components of articles without requiring addition of solvents to the composition before use.

The present invention further includes an article comprising the curable thermally conductive composition and at least two components where the curable thermally conductive composition is between and in contact with the two components of the article. The curable thermally conductive composition can be in either a cured or non-cured form.

The article of the present invention is useful as a device benefiting from efficient thermal conduction between components, such as a heat generating device and at least one of a heat sink, cooling plate, metal cover or other heat dissipating component.

### EXAMPLES

Some embodiments of the invention will now be described in the following Examples, wherein all weight percentages are relative to the weight of the thermally conductive composition and all particle sizes of fillers are D50 particle sizes, unless otherwise specified. Table 1 lists the materials for use in the thermally conductive composition of the samples described herein below. Note: “Vi” represents vinyl and “Me” represents methyl. SYL-OFF is a trademark of Dow Corning Corporation.

TABLE 1

| Component | Description | Source |
|---|---|---|
| Vi Polymer A-1 | Vinyldimethylsiloxy-terminated | Available as SMS-V21 |
| | polydimethylsiloxane (PDMS) with a viscosity of | from Gelest. |
| | 78 mPa*s at 25° C. and 1.25 wt % vinyl relative to | |
| | molecular weight. | |
| SiH Crosslinker | Trimethyl terminated dimethyl-co-hydrogen methyl | Available as HMS-501 |
| B-1 | polysiloxane with a viscosity of 14 mPa*s | from Gelest. |
| | at 25° C. and 0.36 wt % H from SiH. | |
| SiH Crosslinker | Hydride terminated PDMS with a viscosity of 7-10 | Available as DMS-H11 |
| B-2 | mPa*s at 25° C. and 0.16 wt % H from SiH. | from Gelest. |
| Treating Agent | n-Decyltrimethoxysilane | Available as Z-6210 from |
| D-1 | | The Dow Chemical Company. |
| Treating Agent | Monotrimethoxysiloxy and trimethylsiloxy | Synthesize according to the |
| D-2 | terminated PDMS having an average chemical | teachings in US2006/0100336 |
| | structure: Me₃SiO[Me₂SiO]₃₀Si(OMe₃)₃ | (such as paragraphs 101-103) |
| TC Filler C1-1 | Spherical aluminum (Al) particles with | Available from Jiweixin |
| | a D50 of 70 μm | of China |
| TC Filler C1-2 | Spherical aluminum particles with | Available from Jiweixin |
| | a D50 of 90 μm | of China |
| TC Filler C5-1 | Spherical aluminum particles with | Available from Jiweixin |
| | a D50 of 24 μm | of China |
| TC Filler C5-2 | Spherical aluminum particles with | Available from Jiweixin |
| | a D50 of 9 μm | of China |
| TC Filler C4-1 | Spherical aluminum nitride particles with | Available from Bestry |
| | a D50 of 20 μm | of China |
| TC Filler C2-1 | Spherical aluminum oxide particles with | Available from Showa Denko |
| | a D50 of 2 μm | Co., Ltd. of Japan |
| TC Filler C2-2 | Spherical aluminum oxide particles with | Available from Denka Co., |
| | a D50 of 5 μm | Ltd. of Japan |
| TC Filler C2-3 | Irregular aluminum nitride particles with | Available from Maruwa |
| | a D50 of 1.5 μm | of Japan. |
| TC Filler C2-4 | Spherical aluminum particles with | Available from Jiweixin |
| | a D50 of 1.5 μm | of China |
| TC Filler C3-1 | Irregular zinc oxide particles with | Available from Zochem, |
| | a D50 of 0.2 μm | Inc. |
| TC Filler C3-2 | Spherical aluminum oxide particles | Available from Admatechs |
| | with a D50 of 0.5 μm | Co., Ltd. of Japan |
| Catalyst E-1 | Karstedt's Catalyst composition | Available as SYL-OFF ™ |
| | | 4000 catalyst from The |
| | | Dow Chemical Company |
| Inhibitor F-1 | Methyl(tris(1,1-dimethyl-2- | Available as ACM83817714 |
| | propynyloxy))silane | from Alfa Chemistry |

*Viscosities of polysiloxanes were measured by ASTM D445-21 at 25° C.; “TC filler” refers to thermally conductive filler.

### IE 1-8 and CE 1-8 Samples

Formulations for the samples are in Tables 2 and 3, with the amount of each component reported in grams (g). Samples were prepared by using a SpeedMixer™ DAC 400 FVZ mixer from FlackTek Inc. (South Carolina, USA) to mix the components together. To a cup of the SpeedMixer add the Vi Polymer, Crosslinker, Treating Agent, and TC fillers C2 and C3. Mix at 1000 revolutions per minute (RPM) for 20 seconds, then 1500 RPM for 20 seconds. Add half of the TC fillers C1, C4, and C5 if present and mix at 1000 RPM for 20 seconds, then 1500 RPM for 20 seconds. Add the remaining TC fillers and mix in the same way. The resulting composition in the cup was scraped to ensure homogenous mixing and then the Inhibitor F-1 and Catalyst E-1 were added and mixed in like manner to obtain the curable thermally conductive composition samples. The obtained thermally conductive composition samples were evaluated for extrusion rate thermal conductivity, and appearance according to the following test methods:

### Extrusion Rate Test

Determine extrusion rate (“ER”) for a sample using Nordson EFD dispensing equipment. Package sample material into a 30 cubic centimeter syringe with a 2.54 millimeter (mm) opening (EFD syringe form Nordson Company). Dispense sample at 25° C. through the opening by applying a pressure of 0.62 MPa to the syringe. The mass of the sample in grams (g) extruded after one minute corresponds to the extrusion rate in grams per minute (g/min). The objective of the present invention is to achieve an extrusion rate of at least 40 g/min.

Notably, some samples were powdery pastes that could not be extruded so they are reported as having an ER of 0 (and thermal conductivity was not measured, thus reporting as “NA”).

### Thermal Conductivity Test

Determine thermal conductivity by using a hot disk according to ISO 22007-2. The thermal conductivity of cured samples was measured by Hot Disk TPS 2500 S instrument with a 3.189 mm Kapton sensor (model 5465). The cured samples were prepared by curing the curable thermally conductive composition samples at 120° C. for 60 min with dimension of 25 mm*25 mm*8 mm. The objective of the present invention is to achieve a thermal conductivity of at least 10.0 Watts per meter*Kelvin (W/m*K).

### Appearance Test

Determine appearance by visual inspection. Upon mixing all components, the resultant curable thermally conductive composition sample was visually inspected for surface appearance. If the composition shows a uniform surface, it indicates the composition has good uniformity and stability, thereby passing the appearance test. Otherwise, if coarse or powdery surface or oil separation is observed, it fails the appearance test.

Each sample was characterized for extrusion rate using the Extrusion Rate Test, thermal conductivity using the Thermal Conductivity Test, and appearance using the Appearance Test described herein, above.

Table 2 contains characterization results for IEs 1-8 samples. As shown in Table 2, all IEs 1-8 samples achieved both requirements of an ER of at least 40 g/min and a TC of at least 10.0 W/m*K.

Table 3 contains characterization results for CEs 1-8 samples. CE1 through CE5 samples that do not have aluminum filler with a D50 in a range of 60 to 150 μm failed to achieve both an ER of at least 40 g/min and a thermal conductivity (TC) of at least 10 W/m*K even when the samples include just aluminum filler that is smaller than 60 μm. As compared with CE5 sample, CE6 sample comprising the same types of TC fillers at a reduced total concentration achieved ER of 47 g/min but much lower TC than 10 W/m*K. CE7 and CE8 samples that comprise aluminum filler with a D50 of 70 μm at a concentration of 21 wt % and 57.9 wt %, respectively, failed to achieve at least one or both of TC and ER requirements.

TABLE 2

| | IE1 | IE2 | IE3 | IE4 | IE5 | IE6 | IE7 | IE8 |
|---|---|---|---|---|---|---|---|---|
| Component | | | | | | | | |
| Vi polymer A-1 | 2.527 | 2.527 | 2.527 | 2.528 | 2.972 | 2.527 | 2.456 | 2.626 |
| SiH crosslinker B-1 | 0.010 | 0.010 | 0.010 | 0.010 | 0.020 | 0.050 | 0.050 | 0.050 |
| SiH crosslinker B-2 | 0.500 | 0.500 | 0.500 | 0.500 | 0.539 | 0.470 | 0.550 | 0.580 |
| Treating Agent D-1 | 0.200 | 0.200 | 0.200 | 0.200 | 0.200 | 0.200 | 0.200 | |
| Treating Agent D-2 | 1.249 | 1.249 | 1.249 | 1.200 | 1.397 | 1.249 | 1.249 | 1.249 |
| TC Fillers C1-1 | 30.985 | 0.000 | 45.977 | | | 45.972 | 51.964 | 45.968 |
| TC Fillers C1-2 | | 30.985 | | 46.000 | 46.906 | | | |
| TC Fillers C4-1 | 17.991 | 17.991 | | | | | | |
| TC Fillers C2-1 | 31.484 | 31.484 | 33.483 | 33.500 | 16.966 | | | |
| TC Fillers C2-2 | | | | | | 33.480 | 31.978 | 33.477 |
| TC Fillers C2-3 | | | | | 13.972 | | | |
| TC Fillers C3-1 | 14.993 | 14.993 | 15.992 | 16.000 | 16.966 | 15.990 | | 15.989 |
| TC Fillers C3-2 | | | | | | | 11.492 | |
| Catalyst E-1 | 0.060 | 0.060 | 0.060 | 0.060 | 0.060 | 0.060 | 0.060 | 0.060 |
| Inhibitor F-1 | 0.002 | 0.002 | 0.002 | 0.002 | 0.002 | 0.002 | 0.002 | 0.002 |
| Characterization | | | | | | | | |
| Wt % filler | 94.45 | 94.45 | 95.45 | 95.45 | 94.81 | 95.45 | 95.43 | 95.45 |
| Vol % filler | 85.45 | 85.45 | 85.78 | 85.78 | 84.36 | 85.78 | 86.5 | 85.78 |
| Wt % Al (D50 ≥ | 31.0 | 31.0 | 46.0 | 46.0 | 46.9 | 46.0 | 52.0 | 46.0 |
| 60 μm) | | | | | | | | |
| SiH/Vi ratio | 0.60 | 0.60 | 0.60 | 0.60 | 0.58 | 0.68 | 0.79 | 0.78 |
| ER (g/min) | 46 | 52 | 60 | 51 | 40 | 40 | 72 | 73 |
| TC (W/m*K) | 10.8 | 11.55 | 11.14 | 12.28 | 12.19 | 10.57 | 10.45 | 10.71 |
| Appearance | Uniform | Uniform | Uniform | Uniform | Uniform | Uniform | Uniform | Uniform |

Note:
In Table 2 and Table 3 below:
“Wt % filler” refers to wt % of total thermally conductive fillers relative to the total weight of all components in the sample.
“Vol % filler” refers to volume concentration of total thermally conductive fillers relative to the total volume of all components in the sample.
“SiH/Vi ratio” refers to molar ratio of SiH functionality from the crosslinker to vinyl functionality.
“Wt % Al (D50 ≥ 60 μm)” refers to wt % of aluminum particles with D50 ≥ 60 μm relative to the total weight of all components in the sample.
“ER”, “TC” and “Appearance” were evaluated according to the test methods described above.

TABLE 3

| Component | CE1 | CE2 | CE3 | CE4 | CE5 | CE6 | CE7 | CE8 |
|---|---|---|---|---|---|---|---|---|
| Vi polymer A-1 | 2.508 | 2.496 | 2.508 | 2.496 | 3.847 | 4.394 | 2.527 | 2.733 |
| SiH crosslinker B-1 | 0.010 | 0.010 | 0.010 | 0.010 | 0.040 | 0.059 | 0.030 | 0.080 |
| SiH crosslinker B-2 | 0.496 | 0.494 | 0.496 | 0.494 | 0.638 | 0.634 | 0.480 | 0.569 |
| Treating Agent D-1 | 0.198 | 0.197 | 0.198 | 0.197 | 0.199 | 0.198 | 0.200 | |
| Treating Agent D-2 | 1.984 | 2.468 | 1.984 | 2.468 | 1.496 | 1.584 | 1.249 | 1.248 |
| TC Fillers C1-1 | | | | | | | 20.990 | 57.884 |
| TC Fillers C5-1 | 45.635 | 45.410 | 30.754 | 30.602 | | | | |
| TC Fillers C5-2 | | | | | 49.850 | 49.505 | | |
| TC Fillers C4-1 | | | 17.857 | 17.769 | | | 27.986 | |
| TC Fillers C2-1 | 33.234 | 33.070 | 31.250 | 31.096 | | | 31.484 | 29.940 |
| TC Fillers C2-4 | | | | | 25.922 | 25.743 | | |
| TC Fillers C3-1 | 15.873 | 15.795 | 14.881 | 14.808 | 17.946 | 17.822 | 14.993 | |
| TC Fillers C3-2 | | | | | | | | 7.485 |
| Catalyst E-1 | 0.060 | 0.059 | 0.060 | 0.059 | 0.060 | 0.059 | 0.060 | 0.060 |
| Inhibitor F-1 | 0.002 | 0.002 | 0.002 | 0.002 | 0.002 | 0.002 | 0.002 | 0.002 |
| Characterization | | | | | | | | |
| Wt % filler | 94.74 | 94.27 | 94.45 | 94.27 | 93.72 | 93.07 | 94.45 | 95.31 |
| Vol % filler | 83.81 | 82.53 | 85.45 | 82.15 | 82.74 | 81.2 | 85.45 | 86.46 |
| Wt % Al (D50 ≥ | 0.0 | 0.0 | 0.0 | 0.0 | 0.0 | 0.0 | 21.0 | 57.9 |
| 60 μm) | | | | | | | | |
| SiH/Vi ratio | 0.60 | 0.60 | 0.60 | 0.60 | 0.56 | 0.52 | 0.64 | 0.82 |
| ER (g/min) | 0 | 9 | 0 | 11 | 0 | 47 | 29 | 18 |
| TC (W/m*K) | NA | 7.524 | NA | 7.316 | NA | 5.824 | 10.36 | 8.622 |
| Appearance | Powdery | Coarse | Powdery | Coarse | Powdery | Uniform | Uniform | Uniform |

1. A curable thermally conductive composition comprising:
(A) from 1.0 to 4.0 weight-percent of an alkenyl-functional polyorganosiloxane having a viscosity in a range of 25 to 2000 millipascal*seconds as determined by ASTM D445-21 using a glass capillary Cannon-Fenske type viscometer at 25 degrees Celsius, wherein the alkenyl-functional polyorganosiloxane has an average chemical structure (I):
R^{a}_{(3-c)}R′_{c}SiO—(R′R^{a}SiO)ₐ—(R^{a}₂SiO)_{b}—SiR′_{d}R^{a}_{(3-d)} (I)
where R^{a} independently in each occurrence is an alkyl group having 1 to 6 carbon atoms, R′ independently in each occurrence is an alkenyl group, subscript a≥0, subscript b>0, subscript c is zero or 1, subscript d is zero or 1, (a+b) is 20 to 350, and (a+c+d)≥2;
(B) a silyl-hydride functional polysiloxane crosslinker that contains at least two silyl-hydride groups per molecule and that is present at a concentration to provide a molar ratio of silicon-bonded hydrogen atoms to alkenyl groups for the composition of 0.4 to 1.5;
(C) from 94 to 97 weight-percent of thermally conductive fillers comprising:
(c1) from 30 to less than 55 weight-percent of aluminum particles having a D50 in a range of 60 to 150 micrometers;
(c2) from 20 to 40 weight-percent of thermally conductive fillers that have a D50 in a range of 1 to 10 micrometers and that are selected from aluminum oxide, aluminum nitride, or mixtures thereof;
(c3) from 8 to 20 weight-percent of thermally conductive fillers that have a D50 in a range of 0.1 to 0.8 micrometers and that are selected from zinc oxide, aluminum oxide, or mixtures thereof; and
(c4) optionally, from zero to 20 weight-percent of thermally conductive fillers other than (c1), that are aluminum nitride particles having a D50 in a range of 20 to 50 micrometers; and
(D) from 0.1 to 2.5 weight-percent of a filler treating agent comprising a trialkoxysilyl diorganopolysiloxane, and optionally, an alkyl trialkoxysilane;
where weight-percentages are relative to curable thermally conductive composition weight.

2. The curable thermally conductive composition of claim 1, further comprising a platinum-based hydrosilylation reaction catalyst in an amount sufficient to provide a platinum concentration of 0.01 to 0.5 weight-percent, based on the weight of the curable thermally conductive composition.

3. The curable thermally conductive composition of claim 1, further comprising a hydrosilylation reaction inhibitor at a concentration of 0.001 to 0.3 weight-percent, based on the weight of the curable thermally conductive composition.

4. The curable thermally conductive composition of claim 1, wherein the alkenyl-functional polyorganosiloxane comprises a vinyldimethylsiloxy-terminated polydimethylpolysiloxane having the average chemical structure (II):
Vi(CH₃)₂SiO—((CH₃)₂SiO)_{b}—Si(CH₃)₂Vi (II)
where Vi represents vinyl and subscript b has a value of 25 to 350.

5. The curable thermally conductive composition of claim 1, wherein the trialkoxysilyl diorganopolysiloxane is a mono-trialkoxysiloxy terminated diorganopolysiloxane having the average chemical structure (IV):
R^{c}₃SiO[R^{d}₂SiO]_{g}Si(OR^{e})₃ (IV)
where R^{c}, R^{d}, and R^{e} are independently in each occurrence selected from hydrocarbyls having from 1 to 10 carbon atoms, and subscript g has a value of 25 to 110.

6. (canceled)

7. The curable thermally conductive composition of claim 1, wherein the aluminum particles have a D50 of 70 to 95 micrometers.

8. The curable thermally conductive composition of claim 1, wherein the thermally conductive filler comprises: (c1) from 30 to 52 wt % of aluminum particles having a D50 of 70 to 90 μm; (c2) from 30 to 35 wt % of aluminum oxide having a D50 of 2 to 5 μm, or a combination of 5 to 25 wt % of aluminum oxide having a D50 of 2 to 5 μm and 5 to 20 wt % of aluminum nitride having a D50 of 1 to 5 μm; (c3) from 12 to 18 wt % of zinc oxide having a D50 of 0.1 to 0.5 μm, or from 8 to 13 wt % of aluminum oxide having a D50 of 0.2 to 0.8 μm; and optionally (c4) from zero to 20 wt % of aluminum nitride having a D50 of 20 to 50 μm.

9. A process for using the curable thermally conductive composition of claim 1, the process comprising: applying the curable thermally conductive composition between and in contact with two components and then curing the curable composition while in place between the components.

10. The process of claim 9, wherein the applying of the curable thermally conductive composition involves extruding the curable thermally conductive composition.

11. An article comprising the curable thermally conductive composition of claim 1 between and in contact with two components of the article, wherein the curable thermally conductive composition is in either a cured or non-cured form.
